(19) United States
(12) Patent Application Publication
(10) Pub. No.: US 2026/0016343 A1
(43) Pub. Date: Jan. 15, 2026

(54) INFRARED BOLOMETER USING SEMICONDUCTING CARBON NANOTUBES AND METHOD FOR MANUFACTURING THE SAME

(71) Applicant: NEC Corporation, Tokyo (JP)

(72) Inventor: Tomo TANAKA, Tokyo (JP)

(73) Assignee: NEC Corporation, Tokyo (JP)

(21) Appl. No.: 19/248,604

(22) Filed: Jun. 25, 2025

(30) Foreign Application Priority Data
Jul. 9, 2024 (JP) 2024-109974

(51) Int. Cl. G01J 5/22; G01J 5/20; H10F 30/282; H10F 71/00; H10F 77/122

(52) U.S. Cl. CPC G01J 5/22; H10F 30/282; H10F 71/1215; H10F 77/122; G01J 2005/204

(57) ABSTRACT

To reduce the resistance value of an infrared bolometer using semiconducting carbon nanotubes.

An infrared bolometer comprising:
a substrate;
an infrared detection unit; and
at least one support leg configured to support the infrared detection unit in such a way that the infrared detection unit is separated from one surface of the substrate, wherein
the infrared detection unit comprises
a source electrode and a drain electrode spaced apart from each other,
a carbon nanotube film present between the source electrode and the drain electrode, at least partially overlapping and being electrically in contact with the source electrode and the drain electrode, and serving as a light detection unit, and
a gate electrode provided over or below the carbon nanotube film with an insulating film interposed, and
a voltage is applied between the source electrode and the drain electrode, and the gate electrode is electrically short-circuited to either the source electrode or the drain electrode.

This application is based upon and claims the benefit of priority from Japanese patent application No. 2024-109974, filed on Jul. 9, 2024, the disclosure of which is incorporated herein in its entirety by reference.

### TECHNICAL FIELD

The present disclosure relates to an infrared bolometer using semiconducting carbon nanotubes and a method for manufacturing the same.

### BACKGROUND ART

Infrared sensors have an extremely wide range of applications such as not only monitoring cameras for security, but also thermography for human body, in-vehicle cameras, and inspection of structures, foods, and the like, and are thus actively used in industrial applications in recent years. In particular, development of a low-cost and high-performance infrared sensor capable of obtaining biological information in cooperation with Internet of Things (IoT) is expected.

A bolometer, which is one of uncooled infrared detectors, has various applications as an inexpensive infrared sensor. For example, JP 2007-263769 A discloses an infrared sensor including a base substrate, a temperature detection unit that absorbs infrared rays and detects a temperature change, and a heat insulation unit that supports the temperature detection unit in such a way that the temperature detection unit is separated from one surface of the base substrate and thermally insulates the temperature detection unit from the base substrate. In a case where this infrared sensor is irradiated with infrared rays, the temperature detection unit is heated, and a resistance change due to a temperature change is detected. In such an infrared sensor, vanadium oxide is used for the temperature detection unit.

### CITATION LIST

### Patent Literature

Patent Literature 1: Japanese patent publication No. 2007-263769

### SUMMARY OF INVENTION

### Technical Problem

However, vanadium oxide used as a bolometer film has a problem that the performance thereof is limited due to a low temperature coefficient of resistance (TCR). In order to improve performance, it is required to use a material having a higher TCR for a bolometer thin film part, and a random network of semiconductor carbon nanotubes (CNT), a material having a high TCR, is expected to be used as a bolometer film.

On the other hand, since semiconducting-type CNT has a high TCR but a large resistance value, an infrared sensor using the semiconducting-type CNT for a bolometer part has a problem of a low signal-to-noise ratio (S/N). Therefore, in order to put an infrared sensor (CNT uncooled infrared sensor) with carbon nanotubes into practical use, it is necessary to reduce the resistance in addition to improving the TCR. In view of the above-mentioned problems, an object of the present disclosure is to reduce the resistance value of an infrared bolometer using semiconducting carbon nanotubes.

### Solution to Problem

In order to achieve the above-described object, an infrared bolometer of the present disclosure includes:
a substrate;
an infrared detection unit; and
at least one support leg configured to support the infrared detection unit in such a way that the infrared detection unit is separated from one surface of the substrate, in which
the infrared detection unit includes
a source electrode and a drain electrode spaced apart from each other,
a carbon nanotube film present between the source electrode and the drain electrode, at least partially overlapping and being electrically in contact with the source electrode and the drain electrode, and serving as a light detection unit, and
a gate electrode provided over or below the carbon nanotube film with an insulating film interposed, and
a voltage is applied between the source electrode and the drain electrode, and the gate electrode is electrically short-circuited to either the source electrode or the drain electrode.

In addition, a method for manufacturing an infrared bolometer of the present disclosure including an infrared detection unit supported over a substrate by at least one support leg in such a way as to be separated from the substrate includes
manufacturing the infrared detection unit, in which the manufacturing includes:
(ta) forming a first insulating film;
(tb) forming a carbon nanotube film into a predetermined shape;
(tc) forming a source electrode and a drain electrode to be electrically in contact with at least a part of the carbon nanotube film at an interval;
(td) forming a second insulating film on the carbon nanotube film, the source electrode, and the drain electrode; and
(te) forming, on the second insulating film, a gate electrode overlapping at least a part of the carbon nanotube film with the second insulating film interposed, and being electrically connected to the drain electrode.

Alternatively, a method for manufacturing an infrared bolometer of the present disclosure including an infrared detection unit supported over at least one substrate by at least one support leg in such a way as to be separated from the substrate includes
manufacturing the infrared detection unit, in which the manufacturing includes:
(ba) forming a first insulating film;
(bb) forming a gate electrode with a predetermined shape;
(bc) forming a second insulating film;
(bd) forming a carbon nanotube film into a predetermined shape; and
(be) forming a source electrode and a drain electrode to be electrically in contact with at least a part of the carbon nanotube film at an interval, and connecting the drain electrode to the gate electrode.

### Advantageous Effect of Invention

According to the present disclosure, it is possible to provide an infrared bolometer comprising a low resistance value and a method for manufacturing the same.

### BRIEF DESCRIPTION OF DRAWINGS

FIG. 1 is a perspective view of a bolometer array of the present disclosure.

FIG. 2 is a perspective view of a single bolometer element according to the present disclosure.

FIG. 3 is a top view of an example of a top-gate infrared bolometer of the present disclosure.

FIG. 4A is a top transmission view of an example of a top-gate type infrared bolometer of the present disclosure.

FIG. 4B is a top transmission view of an example of a top-gate type infrared bolometer of the present disclosure.

FIG. 5A is a cross-sectional view of an example of a top-gate infrared bolometer according to the present disclosure.

FIG. 5B is a cross-sectional view of an example of a top-gate infrared bolometer according to the present disclosure.

FIG. 6A is a top transmission view of an example of a top-gate type infrared bolometer according to the present disclosure.

FIG. 6B is a cross-sectional view of an example of a top-gate type infrared bolometer according to the present disclosure.

FIG. 7A is a top transmission view of an example of a top-gate type infrared bolometer according to the present disclosure.

FIG. 7B is a cross-sectional view of an example of a top-gate type infrared bolometer according to the present disclosure.

FIG. 8A is a top transmission view of an example of a top-gate type infrared bolometer according to the present disclosure.

FIG. 8B is a cross-sectional view of an example of a top-gate type infrared bolometer according to the present disclosure.

FIG. 9A is a top transmission view of an example of a back-gate type infrared bolometer according to the present disclosure.

FIG. 9B is a cross-sectional view of an example of a back-gate type infrared bolometer according to the present disclosure.

FIG. 10A is a top transmission view of an example of a back-gate type infrared bolometer according to the present disclosure.

FIG. 10B is a cross-sectional view of an example of a back-gate type infrared bolometer according to the present disclosure.

FIG. 11A is a top transmission view of an example of a back-gate type infrared bolometer according to the present disclosure.

FIG. 11B is a cross-sectional view of an example of a back-gate type infrared bolometer according to the present disclosure.

FIG. 12A is a top transmission view of an example of a back-gate type infrared bolometer according to the present disclosure.

FIG. 12B is a cross-sectional view of an example of a back-gate type infrared bolometer according to the present disclosure.

### EXAMPLE EMBODIMENT

Hereinafter, an example embodiment for carrying out the present disclosure will be described, but the present disclosure is not limited to the following example embodiment. In the following examples, the same or equivalent parts will be denoted by the same reference numerals. In addition, a bolometer (infrared detector) that detects infrared light will be described as an example, but the bolometer of the present disclosure can also be used to detect, for example, a terahertz wave as described later, in addition to infrared rays. Therefore, in the present specification, the terms “infrared ray” and “infrared light” can be appropriately replaced with a desired electromagnetic wave to be detected.

### Infrared Bolometer

An infrared bolometer of the present disclosure includes:
a substrate;
an infrared detection unit; and
at least one support leg configured to support the infrared detection unit in such a way that the infrared detection unit is separated from one surface of the substrate, in which
the infrared detection unit includes
a source electrode and a drain electrode spaced apart from each other,
a carbon nanotube film present between the source electrode and the drain electrode, at least partially overlapping and being electrically in contact with the source electrode and the drain electrode, and serving as a light detection unit, and
a gate electrode provided over or below the carbon nanotube film with an insulating film interposed, and
a voltage is applied between the source electrode and the drain electrode, and the gate electrode is electrically short-circuited to either the source electrode or the drain electrode.

In the following description, it is assumed that the carbon nanotube film is a p-type semiconductor, but an n-type semiconductor can have exactly the same configuration.

In the infrared bolometer of the present disclosure, a gate electrode is placed above or below the carbon nanotube film, which is the light detection unit, via an insulating film, and a gate voltage is applied to the carbon nanotube film, the current flowing through the carbon nanotube film is increased, thereby reducing the resistance value of the infrared bolometer.

In the present disclosure, “above or below the carbon nanotube film” includes above or below the carbon nanotube film present between the source electrode and the drain electrode, as well as above or below the portion where the source electrode or drain electrode and the carbon nanotube film overlap. Herein, “above the portion where the source electrode or drain electrode and the carbon nanotube film overlap” means “above the source electrode or drain electrode provided on the carbon nanotube film” or “above the carbon nanotube film provided on the source electrode or drain electrode”; and “below the portion where the source electrode or drain electrode and the carbon nanotube film overlap” means “below the carbon nanotube film provided under the source electrode or drain electrode” or “below the source electrode or drain electrode provided under the carbon nanotube film”.

There are two types of carbon nanotubes, i.e., semiconducting and metallic, but the carbon nanotube film of the present disclosure generally comprises 67 mass % or more of semiconducting carbon nanotubes of the total amount of carbon nanotubes, and the film as a whole exhibits semiconducting properties. The semiconducting type may be either p-type or n-type. Since p-type semiconducting carbon nanotubes are easier to manufacture than n-type semiconducting carbon nanotubes, the following description will focus on p-type. In the following description, it is assumed that the carbon nanotube film is a p-type semiconductor, but the same configuration can be used in the case of an n-type semiconductor.

In this description, of a pair of electrodes in contact with the carbon nanotube film at a distance, the electrode that provides a ground potential (0 V; reference potential) is referred to as the drain electrode, and the other electrode is referred to as the source electrode. The infrared bolometer of the present disclosure functions as a bolometer by detecting the temperature change in the current between the source electrode and the drain electrode (i.e., the temperature change in the resistance of the carbon nanotube film).

Hereinafter, a bolometer of the present disclosure will be described with reference to the drawings. The drawings illustrate the structure of an infrared bolometer of the present disclosure for clarity, and the scale may not always be correct.

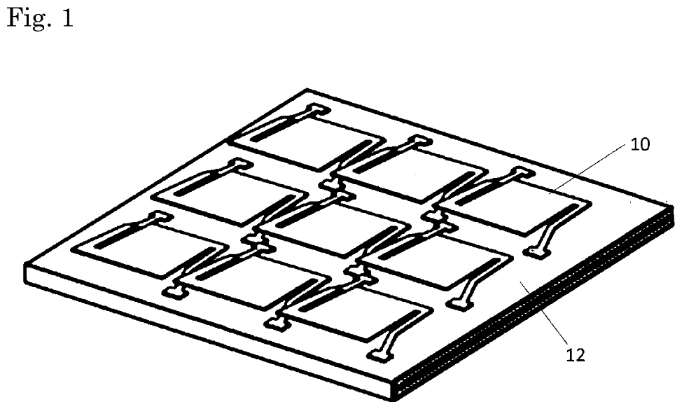

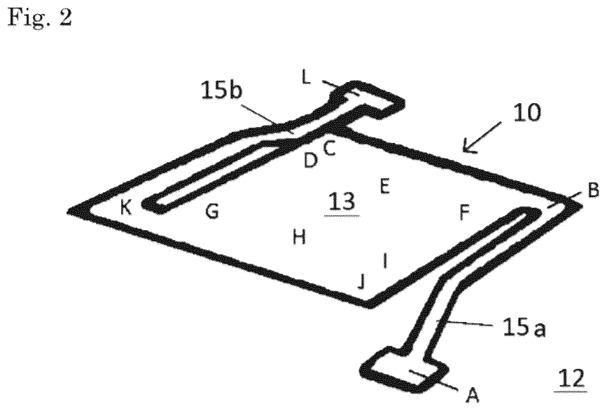

FIG. 1 is a perspective view of a bolometer array, and FIG. 2 is a perspective view of a bolometer single element. The bolometer of the present disclosure has a basic structure, called a MEMS type, and is supported by support legs 15 (a and b) in such a way that an infrared detection unit 13 is separated from a substrate 12. This structure can usually be manufactured by a silicon micro electro mechanical system (MEMS) process. For example, a structure in which the infrared detection unit 13 is separated from the substrate 12 can be manufactured by forming a layer such as an interlayer insulating film on the semiconductor substrate 12, forming a sacrificial layer, forming support legs and a diaphragm part (constituting a bottom surface of the infrared detection unit) that are formed with an insulating film such as a silicon nitride film, and then manufacturing necessary structures such as a metal wiring, a source, and a drain electrode, followed by etching and removing the sacrificial layer. In the present disclosure, the formation of the carbon nanotube film, the source electrode, the drain electrode, and the gate electrode can be performed at an appropriate timing before or after etching and removal of the sacrificial layer.

In the description of the bolometer of the present disclosure, reference numerals A to L indicating positions are used. In FIG. 2, the support leg 15a is in contact with the substrate 12 at an A position, a B position is over or in the same as the diaphragm part disposed at a position away from the substrate 12, and the support leg 15a is away from the substrate 12 in a portion between the A position and the B position. The other support leg 15b is in contact with the substrate 12 at an L position and is away from the substrate 12 in a portion between the L position and a K position. The diaphragm part including the infrared detection unit 13 is supported by the two support legs 15a and 15b.

FIG. 2 is one example of the structure of the bolometer of the present disclosure, it is necessary that the infrared detection unit 13 is configured to be away from the substrate 12, and the structure, the number, and the like of the support legs 15 are not particularly limited.

Hereinafter, the infrared bolometer will be described separately into a top-gate type infrared bolometer having a structure in which a gate electrode is provided over a carbon nanotube film (that is, provided on the opposite side to a substrate described later) with an insulating film interposed and a back-gate type infrared bolometer having a structure in which a gate electrode is provided below a carbon nanotube film (that is, provided over the substrate side) with an insulating film interposed.

### [1] Top-Gate Type (Infrared Bolometer Having Gate Electrode Provided Over Carbon Nanotube Film With Insulating Film Interposed)

In the top-gate type infrared bolometer of the present disclosure, a gate electrode is formed over a carbon nanotube film with an insulating film interposed. The gate electrode in the top-gate type infrared bolometer is preferably disposed in such a way as not to block incidence of light incident on the carbon nanotube film as much as possible.

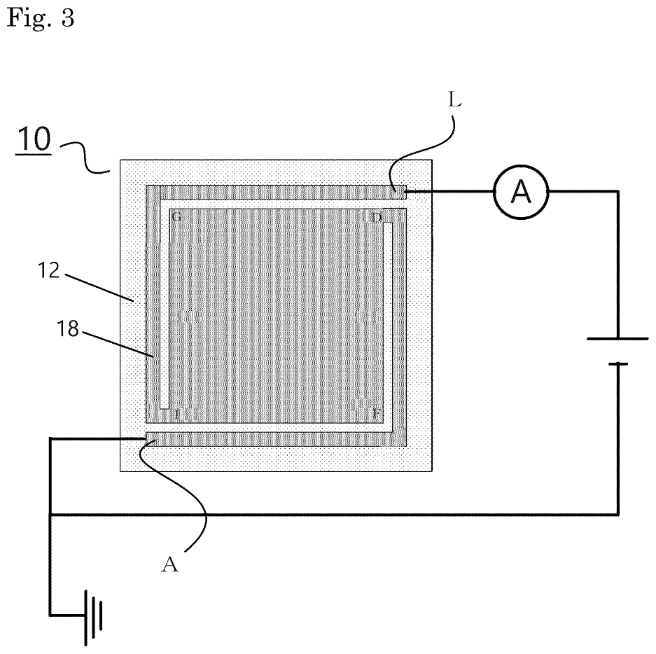

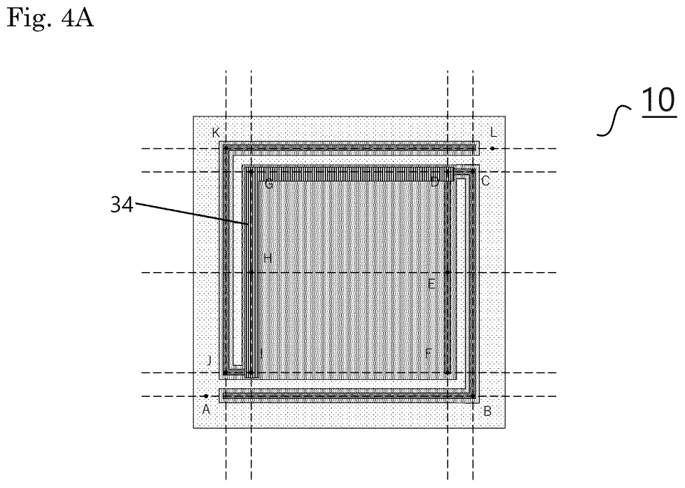

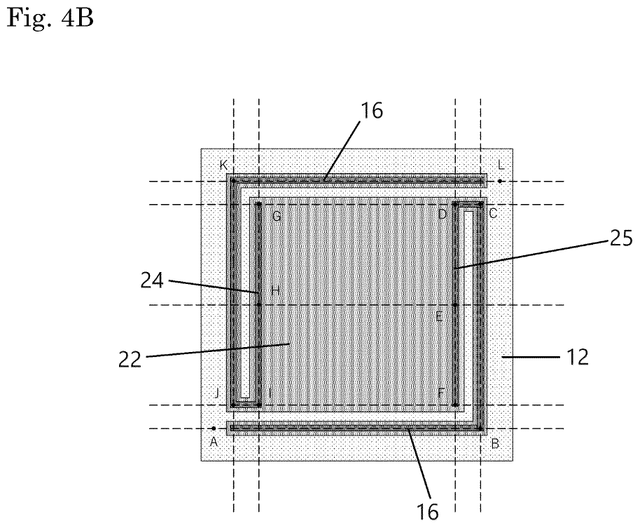

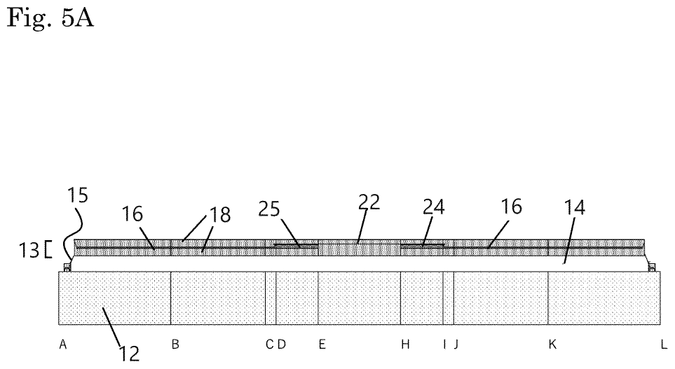

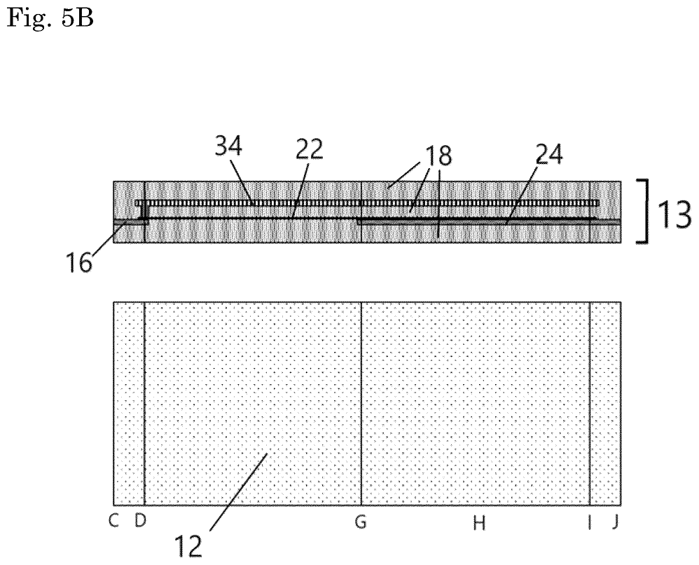

As an example of the top-gate type infrared bolometer, FIG. 3 illustrates a top view of an infrared bolometer in which a gate electrode 34 is disposed in an L shape of D to G to I. FIG. 4A illustrates a top transparent view of the infrared bolometer, and FIG. 4B illustrates a top transparent view of a structure excluding the gate. Furthermore, FIGS. 5A and 5B illustrate cross-sectional views of the infrared bolometer according to the reference numerals corresponding to respective positions. The cross-sectional views illustrated herein are not cross sections taken along a straight line, but are cross sections taken along a bent line connecting the positions of reference numerals with straight lines. In addition, the scale may not always be correct.

As illustrated in FIG. 3, an infrared bolometer 10 of the present disclosure is formed on substrate 12, and the uppermost surface is covered with an insulating film 18. However, layers such as a protective layer and an infrared ray absorption layer may be further formed on the top surface of the insulating film 18. The structure of a lower portion (on the substrate side) of the insulating film 18 will be described with reference to FIGS. 4A and 4B, and 5A and 5B.

As illustrated in FIG. 5A, wirings 16 are connected to a source electrode 24 and a drain electrode 25 through support legs 15 (not illustrated). The source electrode 24 and the drain electrode 25 are provided to face each other at an interval. As illustrated in FIG. 5B, the carbon nanotube film 22 is formed in such a way as to at least partially overlap the upper portions (the opposite side to the substrate) of the source electrode 24 and the drain electrode 25. The carbon nanotube film 22 is present on the opposite side to the substrate with respect to the source electrode 24 and the drain electrode 25. As illustrated in FIG. 4A, the gate electrode 34 is provided in an L shape of D to G to I over the carbon nanotube film 22 with an insulating film 18 interposed. In the gate electrode 34, the portion formed by D to G is present above the carbon nanotube film between the source and the drain, and covers only a part of the carbon nanotube film. This is to prevent incidence of light incident on the carbon nanotube film as much as possible. The portion formed by G to H to I of the gate electrode 34 is provided at a position overlapping the source electrode 24.

As described above, the infrared bolometer 10 illustrated in FIGS. 3, 4A and 4B, and 5A and 5B includes the substrate 12, the infrared detection unit 13, and the support legs 15, and the support legs 15 support the infrared detection unit 13 in such a way that the infrared detection unit 13 is disposed to be separated from one surface of the substrate 12. The infrared detection unit 13 includes the source electrode 24 and the drain electrode 25 spaced apart from each other, a carbon nanotube film 22 present between these two electrodes, at least partially overlapping and being electrically in contact with these two electrodes, and serving as a light detection unit, and the gate electrode 34 provided over the carbon nanotube film 22 in the L shape of D to G to I with the insulating film 18 interposed. A voltage is applied between the source electrode 24 and the drain electrode 25, and the gate electrode 34 is electrically short-circuited to the drain electrode 25 at the position D. In a case where the gate electrode 34 is short-circuited to either the source electrode 24 or the drain electrode 25, integration as a detector is facilitated, which is preferable. The source electrode 24 and the drain electrode 25 may be reversely disposed.

In the infrared bolometer illustrated in FIGS. 3, 4A and 4B, and 5A and 5B, the carbon nanotube film 22 is electrically connected to the source electrode 24 and the drain electrode 25 spaced apart from each other. The source electrode 24 and the drain electrode 25 may be formed by depositing an electrode material in such a way as to be connected to the wirings 16 (referred to as the “contact electrode type”), or may be portions of the wirings 16 in contact with the carbon nanotube film 22 (referred to as the “direct contact type”).

In the top-gate type infrared bolometer, the gate electrode is present “over the carbon nanotube film”. In the present aspect, the gate electrode is present in a part (D to G) of an upper region (a portion not overlapping the source electrode and the drain electrode in the square region of D to F to I to G) between the source electrode and the drain electrode (see FIGS. 4A to 5B), and furthermore, a part of the gate electrode 34 is also present above the source electrode 24 (or may be present above the drain electrode 25) in such a way as to be separated from between the source electrode and the drain electrode (G to H to I). In this regard, the gate electrode 34 is present above the carbon nanotube film 22 with the insulating film interposed (top-gate), and the source electrode 24 (or the drain electrode 25) is disposed below the carbon nanotube film 22 (opposite side to the gate electrode) and in contact with the carbon nanotube film. It is possible to adopt a structure in which the gate electrode is present only in a part (for example, D to G) of the upper region between the source electrode and the drain electrode (the portion not overlapping the source electrode and the drain electrode in the square region of D to F to I to G).

It is considered that in the bolometer having such a structure, in a case where a specific potential is applied to the gate electrode while a voltage is applied between the source and the drain, carriers are induced in the carbon nanotube film, resulting in an increase in the current between the source and the drain. In addition, as in the present aspect, it is considered that in a case where the gate electrode 34 is present above the source electrode 24 (or the drain electrode 25) (see FIG. 5B), and a specific potential is applied to the gate electrode, the Schottky barrier between the source electrode 24 (or the drain electrode 25) and the carbon nanotube film 22 changes, and the current between the source and the drain increases.

The voltage applied to the gate electrode 34 can also be a voltage different from those of the source electrode 24 and the drain electrode 25; however, since wiring is extremely complicated, it is preferable to short-circuit the gate electrode 34 to either the source electrode 24 or the drain electrode 25 as in the present aspect. This facilitates integration as a detector. As in the present aspect, in a case where a part of the gate electrode 34 is present above the source electrode 24, a potential different from that of the source electrode 24 is preferably applied to the gate electrode 34, and in a case where the gate electrode 34 is short-circuited, the gate electrode is thus preferably short-circuited to the drain electrode 25. In contrast, in a case where the gate electrode 34 is present below the drain electrode 25, it is preferable to short-circuit the gate electrode 34 to the source electrode 24.

Each component of the infrared bolometer of the present disclosure will be described.

### Carbon Nanotube Film

The carbon nanotube film is a thin film containing a plurality of carbon nanotubes, preferably having a network structure, and functions as a bolometer film.

The thickness of the carbon nanotube film is not particularly limited, but is, for example, 1 nm or more, for example, several nm to 100 μm, preferably 10 nm to 10 μm, more preferably 50 nm to 1 μum. In one embodiment, it is preferably 20 nm to 500 nm, more preferably 50 nm to 200 nm. When the thickness of the carbon nanotube film is 1 nm or more, a good light absorption rate can be obtained. In addition, it is preferable that the thickness of the carbon nanotube film is 1 μm or less, preferably 500 nm or less, from the viewpoint of simplifying the manufacturing method. In addition, if the carbon nanotube film is too thick, the contact electrode deposited from above may not be in sufficient contact with the carbon nanotubes below the carbon nanotube film, and the effective resistance value may become high, but if it is within the above range, the increase in the resistance value can be suppressed. In addition, when the thickness of the carbon nanotube film is within the above-mentioned range of 10 nm to 1 μm, it is also preferable in that the printing technology can be suitably applied as a manufacturing method of the carbon nanotube film. The thickness of the carbon nanotube film can be obtained as the average value of the thicknesses measured at any 10 points of the carbon nanotube film.

The density of the carbon nanotube film is not particularly limited, but may be, for example, 0.3 g/cm³ to 1.4 g/cm³, preferably 0.8 g/cm³ to 1.3 g/cm³, and more preferably 1.1 g/cm³ to 1.2 g/cm³. When the density of the carbon nanotube film is 0.3 g/cm³ or more, a good light absorption rate can be obtained. When the density of the carbon nanotube film is 0.5 g/cm³ or more, a sufficient light absorption rate can be obtained without providing a mirror (light reflecting layer) or a light absorbing film, and it is preferable in that the element structure can be simplified. The density of the carbon nanotube film can be calculated from the weight, area, and thickness of the carbon nanotube film obtained above.

In addition to the above-mentioned components, the carbon nanotube film may comprise, as appropriate, negative thermal expansion materials, ion conductive agents (surfactants, ammonium salts, inorganic salts), resins and organic binders, which will be described later.

The carbon nanotube content in the carbon nanotube film can be selected as appropriate, but preferably, 0.1 mass % or more is effective based on the total mass of the carbon nanotube film, and more preferably, 1 mass % or more is effective. For example, 30 mass % or even 50 mass % or more is preferable, and in some cases 60 mass % or more may be preferable.

Carbon nanotubes can form, for example, parallel wire, fiber, network, or other structures, but preferably form a three-dimensional network structure which is less prone to aggregation and provides uniform conductive paths.

The carbon nanotubes may be single-walled, double-walled or multi-walled carbon nanotubes, but single-walled or several-walled (e.g., two-walled or three-walled) carbon nanotubes are preferred, and single-walled carbon nanotubes are more preferred. The carbon nanotubes preferably comprise 80% by mass or more of single-walled carbon nanotubes, and more preferably comprise 90% by mass or more (including 100% by mass).

The carbon nanotube film is preferably made of semiconducting carbon nanotubes having a large band gap and carrier mobility. The content of semiconducting carbon nanotubes, preferably semiconducting single-walled carbon nanotubes, in the carbon nanotubes is generally 67% by mass or more, preferably 70% by mass or more, more preferably 80% by mass or more, particularly preferably 90% by mass or more, more preferably 95% by mass or more, and even more preferably 99% by mass or more (including 100% by mass).

The diameter of the carbon nanotube is not particularly limited, but from the viewpoint of increasing the band gap and improving the TCR, it is preferably between 0.6 and 1.5 nm, more preferably between 0.6 and 1.2 nm, and even more preferably between 0.7 and 1.1 nm. In one embodiment, the diameter of the carbon nanotube may be particularly preferable for the diameter to be 1 nm or less. If the diameter of the carbon nanotube is 0.6 nm or more, the production of the carbon nanotube is easier. If the diameter of the carbon nanotube is 1.5 nm or less, it is easier to maintain the band gap in an appropriate range, and a high TCR can be obtained.

In the present specification, the diameter of the carbon nanotubes means that the diameters of about 100 points of the carbon nanotubes on the heat insulating layer or in the formed thin film are measured using an atomic force microscope (AFM), and 60% or more, preferably 70% or more, in some cases more preferably 80% or more, and more preferably 100% of the diameters are within the range of 0.6 to 1.5 nm. Preferably, 60% or more, preferably 70% or more, in some cases more preferably 80% or more, and more preferably 100% of the diameters are within the range of 0.6 to 1.2 nm, and even more preferably 0.7 to 1.1 nm. In one embodiment, 60% or more, preferably 70% or more, in some cases more preferably 80% or more, and more preferably 100% of the diameters are within the range of 0.6 to 1 nm.

The length of the carbon nanotubes is not particularly limited, but is preferably between 100 nm and 5 μm because it is easy to disperse and has excellent coating properties. From the viewpoint of the electrical conductivity of the carbon nanotubes, the length is preferably 100 nm or more. If the length of the carbon nanotubes is 5 μm or less, aggregation on the heat insulating layer and/or during film formation is easily suppressed. The length of the carbon nanotubes is more preferably 500 nm to 3 μm, and even more preferably 700 nm to 1.5 μm.

In the present specification, the length of carbon nanotubes means that at least 100 tubes are observed and counted using an atomic force microscope (AFM) to measure the distribution of the lengths of the carbon nanotubes, and 60% or more, preferably 70% or more, in some cases more preferably 80% or more, and more preferably 100% of the tubes are in the range of 100 nm to 5 μm. Preferably, 60% or more, preferably 70% or more, in some cases more preferably 80% or more, and more preferably 100% of the tubes are in the range of 500 nm to 3 μm. More preferably, 60% or more, preferably 70% or more, in some cases more preferably 80% or more, and more preferably 100% of the tubes are in the range of 700 nm to 1.5 μm.

When the diameter and length of the carbon nanotube are within the above ranges, the effect of semiconductivity becomes large and a large current value can be obtained, so that when used as a bolometer film, a high TCR value is likely to be obtained.

The carbon nanotubes may be heat-treated in an inert atmosphere in a vacuum to remove surface functional groups, impurities such as amorphous carbon and catalysts. The heat treatment temperature can be appropriately selected, but is preferably 800 to 2000° C., more preferably 800 to 1200° C.

### Substrate

The material constituting the substrate may be an inorganic material or an organic material, and any material used in the art may be used without any particular limitation. Inorganic materials include, but are not limited to, glass, Si, SiO₂ and SiN. Organic materials include, but are not limited to, plastics and rubber such as polyimide, polyethylene, polypropylene, polystyrene, polyvinyl chloride, polyethylene terephthalate, acrylonitrile styrene resin, acrylonitrile butadiene styrene resin, fluororesin, methacrylic resin, and polycarbonate.

The substrate is preferably covered with a resin film, which is made of a resin having high heat insulation properties (low thermal conductivity). By covering the substrate surface with a resin with high thermal insulation, it is possible to suppress the dissipation of heat from the carbon nanotube film. The thermal conductivity of the resin constituting the resin film is generally 0.3 W/mK or less, preferably 0.15 W/mK or less, and more preferably 0.1 W/mK or less in some cases. Since a lower thermal conductivity is preferable, the lower limit is not particularly limited, but is, for example, 0.02 W/mK or more, for example, 0.05 W/mK or more. In particular, it is preferable that the thermal conductivity of the resin film at least in the vertical direction (i.e., the lamination direction) is within the above range. In the present specification, the thermal conductivity can be a value obtained at 25° C. according to a standard method (ASTM C177, ASTM E1461, etc.).

The resin used for the resin film is not particularly limited, but may be parylene. Parylene is a general term for paraxylylene-based polymers, and has a structure in which benzene rings are linked via CH₂. Examples of parylene include those formed from a dimer represented by the following formula:

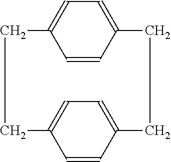 [SMILES: c1cc2ccc1CCc1ccc(cc1)CC2]

In the above formula, at least one hydrogen atom of at least one benzene ring may be substituted with a halogen atom. Examples of halogen include fluorine (F), chlorine (Cl), bromine (Br), and iodine (I), and chlorine is preferred. The number of substitutions by halogen is 8 or less, preferably 6 or less, and more preferably 4 or less.

Parylene includes Parylene N, Parylene C, Parylene D, Parylene HT, and ParyFree, among which Parylene C (thermal conductivity: 0.084 (W/mK)) is the most suitable because it has the lowest thermal conductivity. Parylene is chemically stable and has excellent moisture, chemical, and insulation barrier properties. Parylene coating also has excellent temperature stability, mechanical properties, and tensile strength.

The method of forming the resin film is not particularly limited and can be appropriately selected according to the resin used. For example, when parylene is used, a parylene film can be formed by coating parylene on a substrate using a vacuum deposition apparatus. Specifically, when a solid dimer is heated under vacuum, it vaporizes and becomes a dimer gas. This gas is thermally decomposed to cleave the dimer and become a monomer form. In a deposition chamber at room temperature, this monomer gas polymerizes on all surfaces to form a thin and transparent polymer film. If necessary, the substrate may be pretreated, cleaned, and areas that should not be deposited may be masked before the deposition process.

### Gate Electrode

For the gate electrode, for example, a single metal such as titanium, gold, platinum, aluminum, copper, silver, tungsten, or cobalt, or an alloy containing at least one of these can be used alone or in combination. Two or more kinds of metals may be used in combination, such as gold laminated on titanium, in consideration of adhesion and bonding characteristics with an insulating film or a source electrode and gate electrode described later. As a material for the gate electrode, the same material as the source electrode and drain electrode, or the wiring described later may be used, or a different material may be used. The gate electrode can be formed by deposition or a printing method after patterning with a metal mask or the like as necessary.

### Source Electrode/Drain Electrode/Wiring

The source electrode, the drain electrode, and the wiring may be appropriately selected in consideration of adhesiveness or bonding characteristics with the carbon nanotube film, and the like, and for example, a single metal such as titanium, gold, platinum, aluminum, copper, silver, tungsten, or cobalt, or an alloy containing at least one of these can be used alone or in combination. As a material for the source electrode and drain electrode, the same material as the wiring may be used, or a different material may be used. The heights of the source electrode and the drain electrode can be appropriately adjusted, and are preferably 10 nm to 1 mm, more preferably 50 nm to 1 μm, and particularly preferably 50 nm to 200 nm. The distance between the source electrode and the drain electrode is preferably 1 μm to 500 μm, and more preferably 5 to 200 μm for miniaturization. A method for forming the source electrode and the drain electrode is not particularly limited, and the source electrode and the drain electrode can be formed by, for example, vapor deposition, two sputtering, or printing. As necessary, masking or the like of a region where the source electrode and the drain electrode are not required to be formed may be performed in advance.

### Insulating Film

The material of the insulating film is not particularly limited, but examples include silicon oxide (SiO2) and silicon nitride film (SiN). The method of forming the insulating film is not particularly limited, and can be appropriately selected according to the material used. Since the insulating film becomes a gate insulating film, it can have a thickness equivalent to that of a gate insulating film in a metal oxide semiconductor field effect transistor (MOSFET), for example, preferably 1 nm to 1 μm, more preferably 5 nm to 200 nm

### Infrared Reflector

It is preferable that the infrared bolometer of the present disclosure optionally includes an infrared reflector (not illustrated) over the substrate. The infrared reflector is a layer that reflects light transmitted without being absorbed by the carbon nanotube film and causes the carbon nanotube film to reabsorb the light. The infrared reflector is preferably disposed at a position where a distance between the carbon nanotube film and the infrared reflector satisfies d=λ/4 in consideration of a wavelength λ of light to be absorbed. The infrared reflector is preferably present at a position immediately above the carbon nanotube film. As the infrared reflector, any material that is used as a light reflecting layer in a bolometer can be used without any restrictions, and generally includes metals such as titanium, gold, silver, and aluminum, and can be formed by deposition, sputtering, plating, and the like. The thickness of the mirror is not particularly limited, but is preferably 0.1 to 5 μm, and more preferably 0.5 to 1 μm.

### Protective Film (or Light-Absorbing and Protective Film)

A protective film (not illustrated) may be optionally present on the top of the infrared detection unit of the infrared bolometer of the present disclosure. As the protective film, any material that is used as a protective film in a bolometer can be used without limitation, and examples of the protective film include silicon nitride (SIN), silicon oxide (SiO₂), resins such as acrylic resins such as parylene, PMMA, and PMMA anisole, epoxy resins, and Teflon (registered trademark) films.

It is also preferable to use a material that functions as a light absorbing film-cum-protective film for the protective film. Such materials are preferably silicon nitride (SiN) and silicon oxide (SiO₂). The light absorbing film has the effect of improving the absorption rate of electromagnetic waves. The thickness of the light absorbing film can be appropriately set depending on the material, but can be, for example, 50 nm to 1 μm.

### Another Example of Top-Gate Type

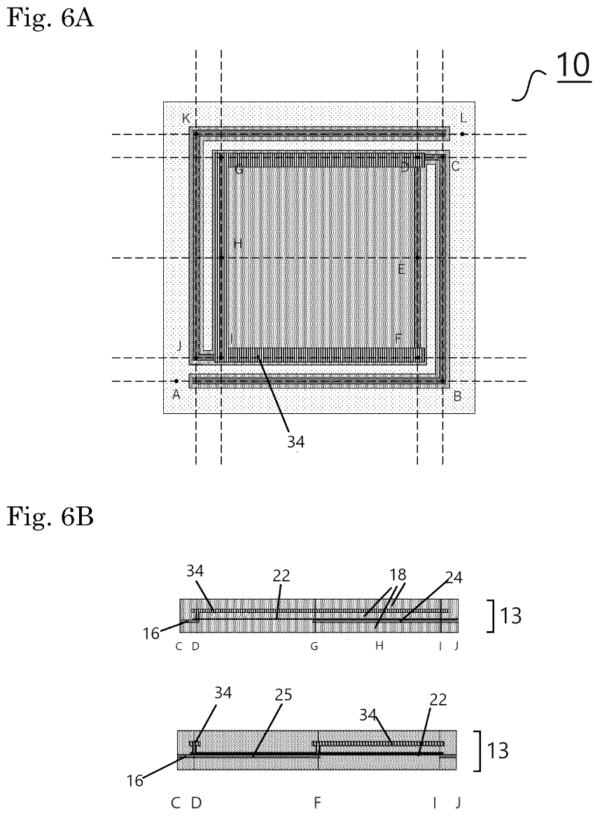

FIGS. 6A and 6B illustrate, as another example of the top-gate type infrared bolometer, a structure of an infrared bolometer in which a gate electrode 34 is disposed in a U shape of D to G to I to F. The gate electrode 34 of the infrared bolometer illustrated in FIGS. 3, 4A and 4B, and 5A and 5B is further extended to the portion formed by I to F. FIG. 6A is a top transparent view of the bolometer, and FIG. 6B is a cross-sectional view according to the reference numerals of the infrared detection unit. In the present aspect, the gate electrode 34 is short-circuited to the drain electrode 25 at positions D and F. As compared with the aspect illustrated in FIGS. 3, 4A and 4B, and 5A and 5B, in the aspect illustrated in FIGS. 6A and 6B, carriers can be induced in the carbon nanotube film also in the lower portion of the gate electrode in the portion formed by I to F, and as a result, the current between the source and the drain can be further increased. On the other hand, the amount of incident infrared rays decreases.

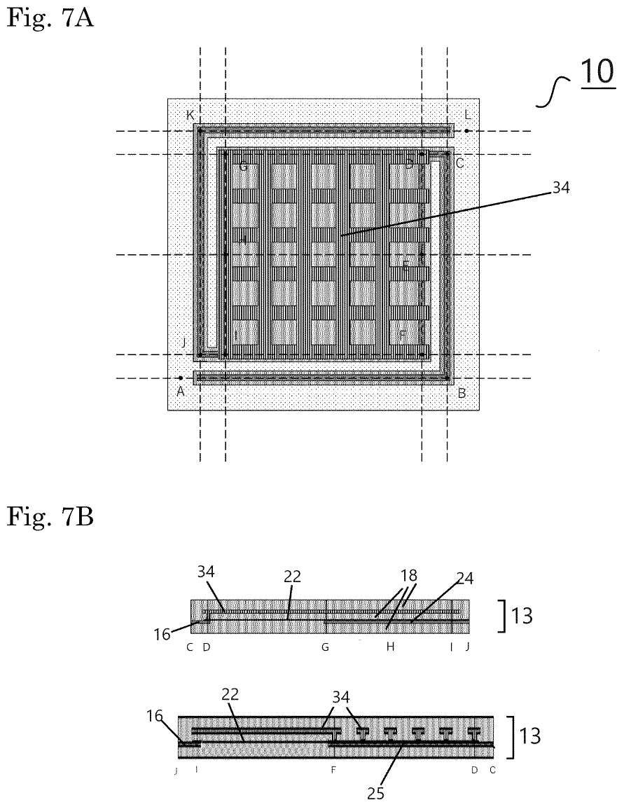

FIGS. 7A and 7B illustrate, as another example of the top-gate type infrared bolometer, a structure of an infrared bolometer in which a gate electrode 34 having a lattice shape is disposed. FIG. 7A is a top transparent view of the bolometer, and FIG. 7B is a cross-sectional view according to the reference numerals of the infrared detection unit. In the present aspect, the gate electrode 34 is short-circuited to the drain electrode 25 at positions D and F. In the aspect illustrated in FIGS. 7A and 7B, since an area of the gate electrode present above between the source electrode and the drain electrode is further increased, carriers can be induced in the carbon nanotube film in a wide area, and the current between the source and the drain can be further increased, while the amount of incident infrared rays further decreases. The area and shape of the gate electrode present above between the source electrode and the drain electrode are preferably set based on a balance between the carrier induction effect in the carbon nanotube film and the amount of incident infrared rays.

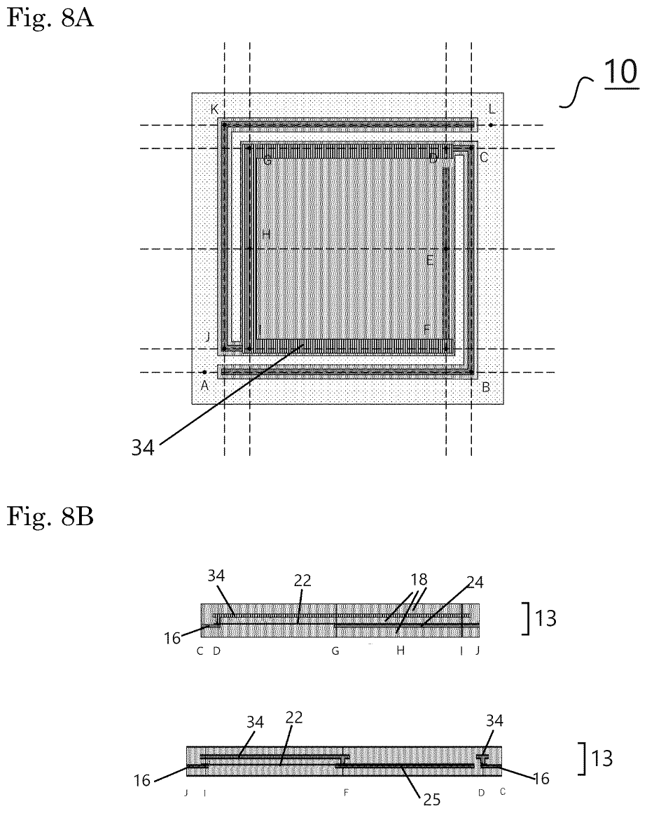

FIGS. 8A and 8B illustrate, as another example of the top-gate type infrared bolometer, a structure of the infrared bolometer in which the gate electrode 34 is disposed in the L shape of D to G to I similarly to the infrared bolometer of FIGS. 3, 4A and 4B, and 5A and 5B, but the drain electrode and the wiring are not connected at the portion D. In this example, the gate electrode 34 is short-circuited to the drain electrode 25 at the position F. That is, in the infrared bolometers of the three examples illustrated in FIGS. 3, 4A and 4B, and 5A and 5B, 6A and 6B, and 7A and 7B, the electrical connection is made in the order of the wiring, the drain electrode, and the gate electrode, but in the aspect of FIGS. 8A and 8B, the electrical connection is made in the order of the wiring, the gate electrode, and the drain electrode.

The shape and electrical connection of the gate electrode in the top-gate type infrared bolometer can be variously changed, and are not limited to those described above.

[2] Back-Gate Type (Infrared Bolometer Having Gate Electrode Provided Below Carbon Nanotube Film With Insulating Film Interposed)

In the back-gate type infrared bolometer of the present disclosure, a gate electrode is formed below a carbon nanotube film (on the substrate side) with an insulating film interposed.

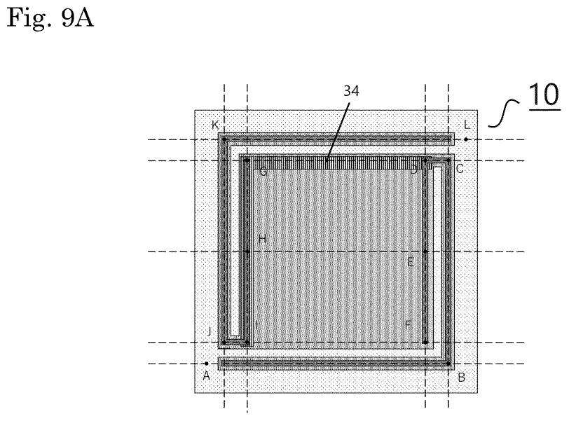

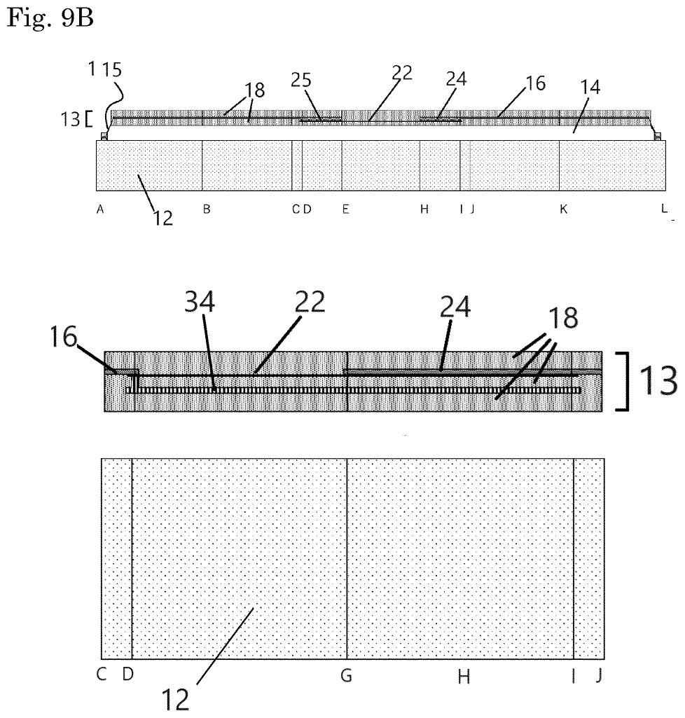

As an example of the back-gate type infrared bolometer, FIG. 9A illustrates a top transparent view of the infrared bolometer in which a gate electrode 34 is disposed in an L shape of D to G to I, and FIG. 9B illustrates a cross-sectional view according to the reference numerals.

An infrared bolometer 10 of the present aspect is formed on a substrate 12, and the uppermost surface is covered with an insulating film 18. However, layers such as a protective layer and an infrared ray absorption layer may be further formed on the top surface of the insulating film. The structure of a lower portion (on the substrate side) of the insulating film 18 will be described with reference to FIGS. 9A and 9B.

As illustrated in FIG. 9A, wirings 16 are connected to a source electrode 24 and a drain electrode 25 through support legs 15 (not illustrated). The source electrode 24 and the drain electrode 25 are provided to face each other at an interval. As illustrated in FIG. 9B, the carbon nanotube film 22 is formed in such a way as to at least partially overlap the lower portions (on the substrate side) of the source electrode 24 and the drain electrode 25. The carbon nanotube film 22 is present on the substrate side with respect to the source electrode 24 and the drain electrode 25. As illustrated in FIG. 9A, the gate electrode 34 is provided in an L shape of D to G to I below the carbon nanotube film 22 with an insulating film 18 interposed. In the gate electrode 34, the portion formed by D to G is present below the carbon nanotube film between the source and the drain. The portion formed by G to H to I of the gate electrode 34 is provided at a position overlapping the source electrode 24.

As described above, the infrared bolometer 10 illustrated in FIGS. 9A and 9B includes the substrate 12, the infrared detection unit 13, and the support legs 15, and the support legs 15 support the infrared detection unit in such a way that the infrared detection unit is disposed to be separated from one surface of the substrate. The infrared detection unit 13 includes the source electrode 24 and the drain electrode 25 spaced apart from each other, a carbon nanotube film 22 present between these two electrodes, at least partially overlapping and being electrically in contact with these two electrodes, and serving as a light detection unit, and the gate electrode 34 provided below the carbon nanotube film 22 in the L shape of D to G to I with the insulating film 18 interposed. A voltage is applied between the source electrode 24 and the drain electrode 25, and the gate electrode 34 is electrically short-circuited to the drain electrode 25 at the position D. In a case where the gate electrode 34 is short-circuited to either the source electrode 24 or the drain electrode 25, integration as a detector is facilitated, which is preferable. The source electrode 24 and the drain electrode 25 may be reversely disposed.

In this aspect, since (1) the gate electrode, (2) the carbon nanotube film, and (3) the source electrode and the drain electrode are formed in this order from the substrate side, connection between the gate electrode 34 and the drain electrode 25 is performed through a through-hole provided in the insulating film 18 as illustrated in the position D of FIG. 9B.

The source electrode 24 and the drain electrode 25 may be formed by depositing an electrode material in such a way as to be connected to the wirings 16 (referred to as the “contact electrode type”), or may be portions of the wirings 16 in contact with the carbon nanotube film 22 (referred to as the “direct contact type”).

In the back-gate type of the present aspect, the gate electrode is present “below the carbon nanotube film”. In FIGS. 9A and 9B, the gate electrode is present in a part (D to G) of a lower region (a portion not overlapping the source electrode and the drain electrode in the square region of D to F to I to G) between the source electrode and the drain electrode, and furthermore, a part of the gate electrode 34 is also present below the source electrode 24 (or the drain electrode 25) in such a way as to be separated from between the source electrode and the drain electrode (G to H to I). In this regard, the gate electrode 34 is present below the carbon nanotube film 22 with the insulating film interposed (back-gate), and the source electrode 24 (or the drain electrode 25) is disposed above the carbon nanotube film 22 (opposite side to the gate electrode) and in contact with the carbon nanotube film. It is possible to adopt a structure in which the gate electrode is present only in a part (for example, D to G) of the upper region between the source electrode and the drain electrode (the portion not overlapping the source electrode and the drain electrode in the square region of D to F to I to G).

It is considered that in the bolometer having such a structure, in a case where a specific potential is applied to the gate electrode while a voltage is applied between the source and the drain, carriers are induced in the carbon nanotube film, resulting in an increase in the current between the source and the drain. In addition, as in the present aspect, it is considered that in a case where the gate electrode is present below the source electrode 24 (or the drain electrode 25) (see FIG. 9B), and a specific potential is applied to the gate electrode, the Schottky barrier between the source electrode 24 (or the drain electrode 25) and the carbon nanotube film changes, and the current between the source and the drain increases.

The voltage applied to the gate electrode 34 can also be a voltage different from those of the source electrode 24 and the drain electrode 25; however, since wiring is extremely complicated, it is preferable to short-circuit the gate electrode 34 to either the source electrode 24 or the drain electrode 25 as in the present aspect. This facilitates integration as a detector. As in the present aspect, in a case where a part of the gate electrode is present below the source electrode, a potential different from that of the source electrode is preferably applied to the gate electrode, and in a case where the gate electrode is short-circuited, the gate electrode is thus preferably short-circuited to the drain electrode. In contrast, in a case where the gate electrode is present below the drain electrode, it is preferable to short-circuit the gate electrode to the source electrode.

### Another Example of Back-Gate Type

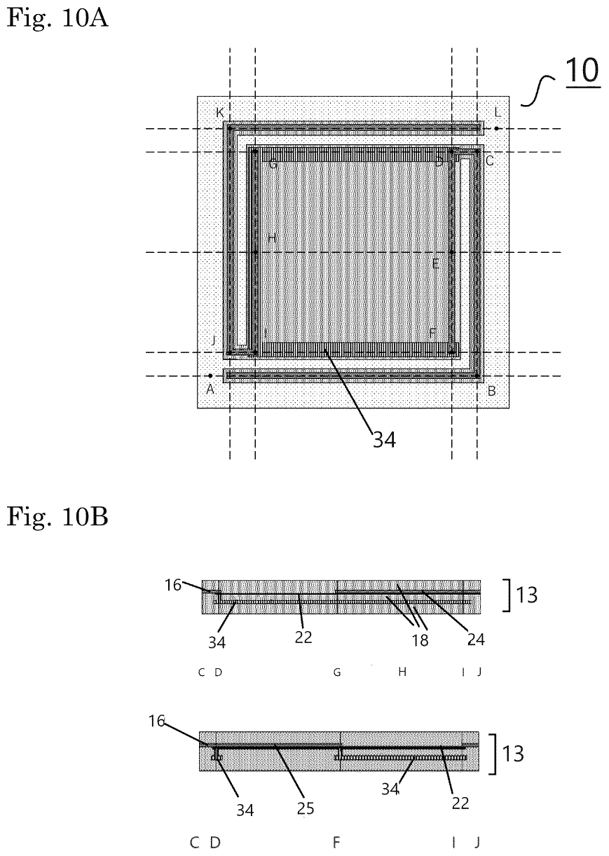

FIGS. 10A and 10B illustrate, as another example of the back-gate type infrared bolometer, a structure of an infrared bolometer in which a gate electrode 34 is disposed in a U shape of D to G to I to F. The gate electrode 34 of the infrared bolometer illustrated in FIGS. 9A and 9B is further extended to the portion formed by I to F. FIG. 10A is a top transparent view of the bolometer, and FIG. 10B is a cross-sectional view according to the reference numerals of the infrared detection unit. In the present aspect, the gate electrode 34 is short-circuited to the drain electrode 25 at positions D and F. As compared with the aspect illustrated in FIGS. 9A and 9B, in the aspect illustrated in FIGS. 10A and 10B, carriers can be induced in the carbon nanotube film also in the upper portion of the gate electrode in the portion formed by I to F, and as a result, the current between the source and the drain can be further increased. On the other hand, as described above, in a case where the infrared reflector is provided on the substrate or the like, the amount of infrared rays received by the infrared detection unit 13 may decrease.

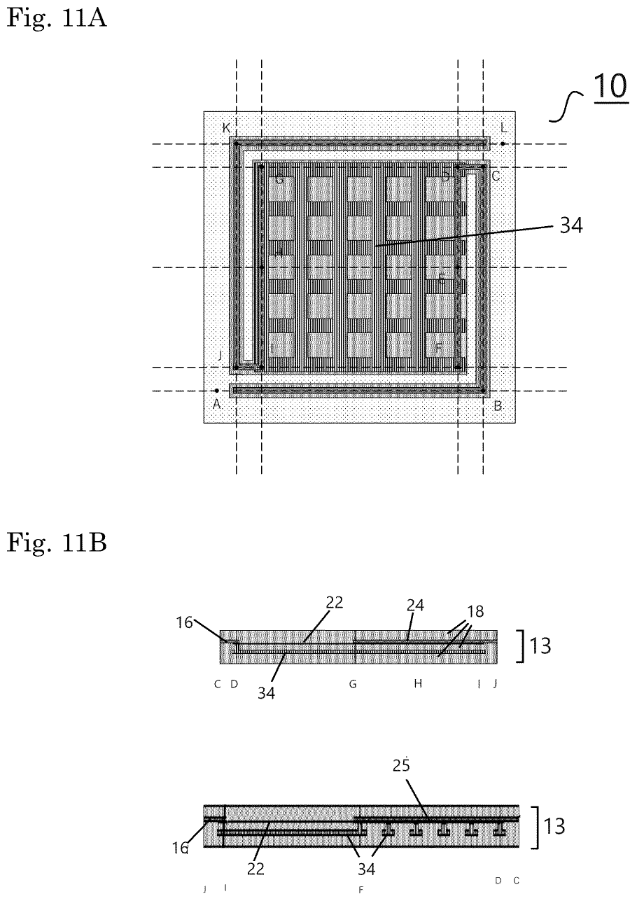

FIGS. 11A and 11B illustrate, as another example of the back-gate type infrared bolometer, a structure of an infrared bolometer in which a gate electrode 34 having a lattice shape is disposed. FIG. 11A is a top transparent view of the bolometer, and FIG. 11B is a cross-sectional view according to the reference numerals of the infrared detection unit. In the present aspect, the gate electrode 34 is short-circuited to the drain electrode 25 at positions D and F. In the aspect illustrated in FIGS. 11A and 11B, since an area of the gate electrode present below between the source electrode and the drain electrode is further increased, carriers can be induced in the carbon nanotube film in a wide area, and the current between the source and the drain can be further increased. On the other hand, as described above, in a case where the infrared reflector is provided on the substrate or the like, the amount of infrared rays received by the infrared detection unit 13 may decrease. The area and shape of the gate electrode present below between the source electrode and the drain electrode are preferably set based on a balance between the carrier induction effect in the carbon nanotube film and the amount of infrared rays received by the infrared detection unit 13.

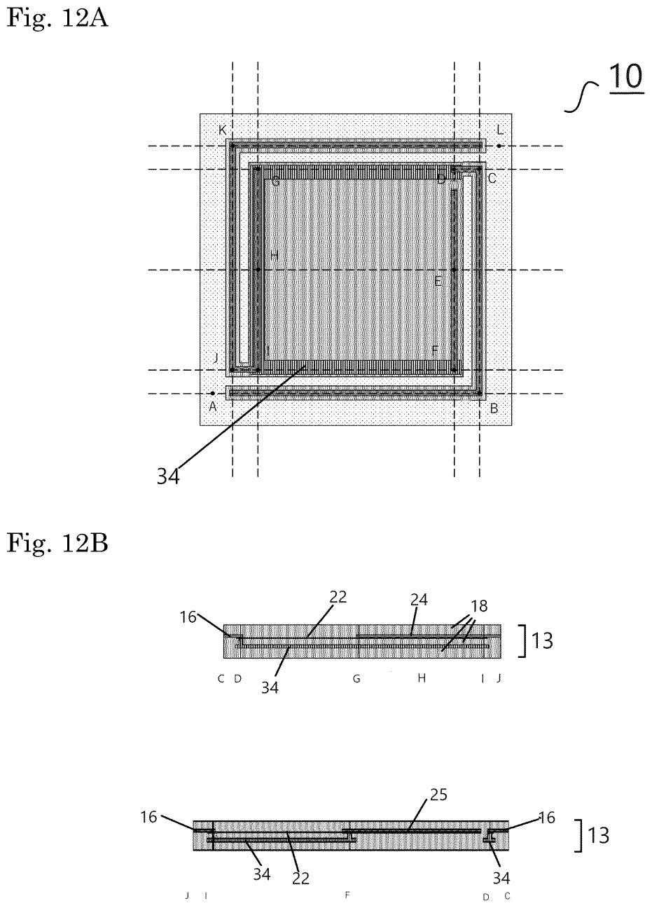

FIGS. 12A and 12B illustrate, as another example of the back-gate type infrared bolometer, a structure of the infrared bolometer in which the gate electrode 34 is disposed in the L shape of D to G to I similarly to the infrared bolometer of FIGS. 9A and 9B, but the drain electrode and the wiring are not connected at the portion D. In this example, the gate electrode 34 is short-circuited to the drain electrode 25 at the position F. That is, in the infrared bolometers of the three examples illustrated in FIGS. 9A and 9B, 10A and 10B, and 11A and 11B, the electrical connection is made in the order of the wiring, the drain electrode, and the gate electrode, but in the aspect of FIGS. 12A and 12B, the electrical connection is made in the order of the wiring, the gate electrode, and the drain electrode.

The shape and electrical connection of the gate electrode in the back-gate type infrared bolometer can be variously changed, and are not limited to those described above.

### Method for Manufacturing Infrared Bolometer

The basic structure of the infrared bolometer of the present aspect can be manufactured with reference to JP 2007-263769 A, and the infrared detection unit in this case may be manufactured to have a structure including a carbon nanotube film as a light detection unit and a top-type or back-type gate electrode.

That is, in one aspect of the manufacturing method, the top-gate type infrared bolometer can be manufactured by the following manufacturing method.

A method for manufacturing an infrared bolometer including an infrared detection unit supported over a substrate by at least one support leg in such a way as to be separated from the substrate, the method including
a step of manufacturing the infrared detection unit, in which the manufacturing step includes:
a step (ta) of forming a first insulating film;
a step (tb) of forming a carbon nanotube film into a predetermined shape;
a step (tc) of forming a source electrode and a drain electrode to be electrically in contact with at least a part of the carbon nanotube film at an interval;
a step (td) of forming a second insulating film on the carbon nanotube film, the source electrode, and the drain electrode; and
a step (te) of forming, on the second insulating film, a gate electrode overlapping at least a part of the carbon nanotube film with the second insulating film interposed, and being electrically connected to the drain electrode.

In the step (te), it is also preferable to form the gate electrode in such a way as to overlap at least a part of the source electrode with the insulating film interposed.

Similarly, in one aspect of the manufacturing method, the back-gate type infrared bolometer can be manufactured by the following manufacturing method.

A method for manufacturing an infrared bolometer including an infrared detection unit supported over a substrate by at least one support leg in such a way as to be separated from the substrate, the method including
a step of manufacturing the infrared detection unit, in which the manufacturing step includes:
a step (ba) of forming a first insulating film;
a step (bb) of forming a gate electrode with a predetermined shape;
a step (bc) of forming a second insulating film;
a step (bd) of forming a carbon nanotube film into a predetermined shape; and
a step (be) of forming a source electrode and a drain electrode to be electrically in contact with at least a part of the carbon nanotube film at an interval, and connecting the drain electrode to the gate electrode.

In a case where the gate electrode is formed in the step (bb), it is also preferable to set the shape of the gate electrode in such a way as to overlap at least a part of the source electrode manufactured in the step (be) with the insulating film interposed.

Here, in order to manufacture the “infrared detection unit supported over a substrate by at least one support leg in such a way as to be separated from the substrate”, generally, the manufacturing includes:
a step (A) of forming a sacrificial layer having a predetermined shape on, for example, a semiconductor substrate (on which an interlayer insulating film is formed as necessary);
a step (B1) of forming at least a part of the infrared detection unit on the sacrificial layer, and a step (B2) of forming at least a part of the support leg on the sacrificial layer;
a step (C) of etching and removing the sacrificial layer, forming a gap between the semiconductor substrate and the infrared detection unit, and forming a structure in which the infrared detection unit is supported by the support leg; and
in a case where the infrared detection unit is not completely formed in the step (B), a step (D1) remaining for completing the infrared detection unit, and in a case where the support leg is not completely formed in the step (B), a step (D2) remaining for completing the support leg.

That is, in steps (B1) and (D1), steps (ta) to (te) described above are performed in the manufacture of the top-gate type infrared bolometer, and steps (ba) to (be) described above are performed in the manufacturing of the back-gate type infrared bolometer.

That is, in the manufacturing method of either the top-gate type infrared bolometer or the back-gate type infrared bolometer, the sacrificial layer may be etched and removed at any timing, and the sacrificial layer may be etched and removed after the entire infrared detection unit is incorporated (that is, after step (te) or after step (be)), or the sacrificial layer may be etched and removed after at least a part of the infrared detection unit is formed, for example, after an insulating film constituting the bottom surface is formed (that is, after step (ta) or after step (ba)), or etching and removing the sacrificial layer can be performed at an appropriate timing. The same applies to the support leg, and it is sufficient that the insulating film constituting at least a part of the support leg, for example, the bottom surface side of the support leg, is formed before the sacrificial layer is etched and removed, and furthermore, the sacrificial layer may be etched and removed after the wiring and the insulating film on the wiring are formed.

As the shapes and positional relationships of the carbon nanotube film, the source electrode and the drain electrode, and the gate electrode in the infrared detection unit, those described for the top-gate type infrared bolometer and the back-gate type infrared bolometer can be adopted, and a known method can be used for the manufacturing.

Although one cell (single element) of the bolometer has been described above, an element structure and an array structure that can be used for the bolometer can be applied without particular limitation. For example, the bolometer elements can be arranged in an array to form a bolometer array. An array in which a plurality of elements used for an image sensor is two-dimensionally arranged may be used.

The bolometer using the carbon nanotube film of the present disclosure can be particularly suitably used for detecting an electromagnetic wave having a wavelength of, for example, 0.7 μm to 1 mm in addition to infrared light. Examples of the electromagnetic wave included in the wavelength range include terahertz waves in addition to infrared rays.

While the present disclosure has been described with reference to drawings and the like, the present disclosure is not limited thereto. It will be understood by those of ordinary skill in the art that various changes in form and details may be made therein without departing from the spirit and scope of the present disclosure as defined by the claims.

### Supplementary Note 1

An infrared bolometer comprising:
a substrate;
an infrared detection unit; and
at least one support leg configured to support the infrared detection unit in such a way that the infrared detection unit is separated from one surface of the substrate, wherein
the infrared detection unit comprises
a source electrode and a drain electrode spaced apart from each other,
a carbon nanotube film present between the source electrode and the drain electrode, at least partially overlapping and being electrically in contact with the source electrode and the drain electrode, and serving as a light detection unit, and
a gate electrode provided over or below the carbon nanotube film with an insulating film interposed, and
a voltage is applied between the source electrode and the drain electrode, and the gate electrode is electrically short-circuited to either the source electrode or the drain electrode.

### Supplementary Note 2

The infrared bolometer according to supplementary note 1, wherein an infrared reflector is present over the substrate.

### Supplementary Note 3

The infrared bolometer according to supplementary note 1 or 2, wherein the gate electrode is formed over the carbon nanotube film with an insulating film interposed.

### Supplementary Note 4

The infrared bolometer according to supplementary note 1 or 2, wherein the gate electrode is formed below the carbon nanotube film with an insulating film interposed.

### Supplementary Note 5

The infrared bolometer according to any of the preceding supplementary notes, wherein the infrared detection unit and the support leg has a wiring configured to supply power to the source electrode and/or the drain electrode.

### Supplementary Note 6

The infrared bolometer according to any of the preceding supplementary notes, wherein the infrared bolometer is a bolometer array containing a plurality of the infrared detection units.

### Supplementary Note 7

A method for manufacturing an infrared bolometer including an infrared detection unit supported over a substrate by at least one support leg in such a way as to be separated from the substrate, the method comprising
manufacturing the infrared detection unit, wherein the manufacturing comprises:
(ta) forming a first insulating film;
(tb) forming a carbon nanotube film into a predetermined shape;
(tc) forming a source electrode and a drain electrode to be electrically in contact with at least a part of the carbon nanotube film at an interval;
(td) forming a second insulating film on the carbon nanotube film, the source electrode, and the drain electrode; and
(te) forming, on the second insulating film, a gate electrode overlapping at least a part of the carbon nanotube film with the second insulating film interposed, and being electrically connected to the drain electrode.

### Supplementary Note 8

A method for manufacturing an infrared bolometer including an infrared detection unit supported over a substrate by at least one support leg in such a way as to be separated from the substrate, the method comprising
manufacturing the infrared detection unit, wherein the manufacturing comprises:
(ba) forming a first insulating film;
(bb) forming a gate electrode with a predetermined shape;
(bc) forming a second insulating film;
(bd) forming a carbon nanotube film into a predetermined shape; and
(be) forming a source electrode and a drain electrode to be electrically in contact with at least a part of the carbon nanotube film at an interval, and connecting the drain electrode to the gate electrode.

### EXPLANATION OF REFERENCE

10 Bolometer
12 Substrate
13 Infrared detection unit
15 Support leg
16 Wiring
18 Insulating film
22 Carbon nanotube film
24 Source electrode
25 Drain electrode
34 Gate electrode

1. An infrared bolometer comprising:
a substrate;
an infrared detection unit; and
at least one support leg configured to support the infrared detection unit in such a way that the infrared detection unit is separated from one surface of the substrate, wherein
the infrared detection unit comprises
a source electrode and a drain electrode spaced apart from each other,
a carbon nanotube film present between the source electrode and the drain electrode, at least partially overlapping and being electrically in contact with the source electrode and the drain electrode, and serving as a light detection unit, and
a gate electrode provided over or below the carbon nanotube film with an insulating film interposed, and
a voltage is applied between the source electrode and the drain electrode, and the gate electrode is electrically short-circuited to either the source electrode or the drain electrode.

2. The infrared bolometer according to claim 1, wherein an infrared reflector is present over the substrate.

3. The infrared bolometer according to claim 1, wherein the gate electrode is formed over the carbon nanotube film with an insulating film interposed.

4. The infrared bolometer according to claim 1, wherein the gate electrode is formed below the carbon nanotube film with an insulating film interposed.

5. The infrared bolometer according to claim 1, wherein the infrared detection unit and the support leg has a wiring configured to supply power to the source electrode and/or the drain electrode.

6. The infrared bolometer according to claim 1, wherein the infrared bolometer is a bolometer array containing a plurality of the infrared detection units.

7. A method for manufacturing an infrared bolometer including an infrared detection unit supported over a substrate by at least one support leg in such a way as to be separated from the substrate, the method comprising
manufacturing the infrared detection unit, wherein the manufacturing comprises:
(ta) forming a first insulating film;
(tb) forming a carbon nanotube film into a predetermined shape;
(tc) forming a source electrode and a drain electrode to be electrically in contact with at least a part of the carbon nanotube film at an interval;
(td) forming a second insulating film on the carbon nanotube film, the source electrode, and the drain electrode; and
(te) forming, on the second insulating film, a gate electrode overlapping at least a part of the carbon nanotube film with the second insulating film interposed, and being electrically connected to the drain electrode.

8. A method for manufacturing an infrared bolometer including an infrared detection unit supported over a substrate by at least one support leg in such a way as to be separated from the substrate, the method comprising
manufacturing the infrared detection unit, wherein the manufacturing comprises:
(ba) forming a first insulating film;
(bb) forming a gate electrode with a predetermined shape;
(bc) forming a second insulating film;
(bd) forming a carbon nanotube film into a predetermined shape; and
(be) forming a source electrode and a drain electrode to be electrically in contact with at least a part of the carbon nanotube film at an interval, and connecting the drain electrode to the gate electrode.

9. The infrared bolometer according to claim 2, wherein the gate electrode is formed over the carbon nanotube film with an insulating film interposed.

10. The infrared bolometer according to claim 2, wherein the gate electrode is formed below the carbon nanotube film with an insulating film interposed.

11. The infrared bolometer according to claim 2, wherein the infrared detection unit and the support leg has a wiring configured to supply power to the source electrode and/or the drain electrode.

12. The infrared bolometer according to claim 2. wherein the infrared bolometer is a bolometer array containing a plurality of the infrared detection units.
